(19) United States
(12) Patent Application Publication
(10) Pub. No.: US 2016/0300624 A1
(43) Pub. Date: Oct. 13, 2016

(54) SEMICONDUCTOR MEMORY APPARATUS, REPAIR SYSTEM THEREFOR, AND METHOD FOR MANAGING APPARATUS QUALITY

(71) Applicant: SK hynix Inc., Icheon-si (KR)

(72) Inventor: Jong Sam KIM, Icheon-si (KR)

(21) Appl. No.: 14/744,390

(22) Filed: Jun. 19, 2015

(30) Foreign Application Priority Data
Apr. 10, 2015 (KR) 10-2015-0050953

(51) Int. Cl. G11C 29/04; G11C 29/00; G11C 17/16

(52) U.S. Cl. CPC G11C 29/04; G11C 17/16; G11C 29/78; G11C 29/76

(57) ABSTRACT

A semiconductor memory apparatus may include a chip area configured to include one or more semiconductor memory chips. The semiconductor memory apparatus may include a repair system configured to perform a test for the chip area while the chip area is in a test mode, to determine whether the chip area has been repaired, and to generate the determination of whether the chip area has been repaired as quality information in response to a failure detection signal enabled while the chip area is in the test mode.

### CROSS-REFERENCES TO RELATED APPLICATION

The present application claims priority under 35 U.S.C. §119(a) to Korean application number 10-2015-0050953, filed on Apr. 10, 2015, in the Korean Intellectual Property Office, which is incorporated herein by reference in its entirety as set forth in full.

### BACKGROUND

1. Technical Field

Various embodiments generally relate to a semiconductor integrated apparatus, and more particularly, to a semiconductor memory apparatus, a repair system therefor, and a method for managing an apparatus quality.

2. Related Art

Semiconductor memory chips formed on a wafer may be tested through a test apparatus. Then semiconductor memory chips may be individualized and packetized.

The semiconductor memory chip packetized as an individual chip is subjected to a test process for checking the characteristics and reliability of a product. In this way, it may be possible to determine the presence or absence of a failure of a completed package.

That is, even though no failure has occurred in a wafer level test, since failure may occur in the future, the presence or absence of failure is checked again through a package level test.

When failure is found through the wafer level test or the package level test, a failure address indicating a failed memory cell may be stored in a separate storage space. Furthermore, the failed memory cell may be replaced with an extra memory cell to ensure the yield of a memory apparatus.

### SUMMARY

According to an embodiment, there may be provided a semiconductor memory apparatus. The semiconductor memory apparatus may include a chip area configured to include one or more semiconductor memory chips. The semiconductor memory apparatus may include a repair system configured to perform a test for the chip area while the chip area is in a test mode. The repair system may be configured to determine whether the chip area has been repaired, and to generate the determination of whether the chip area has been repaired as quality information in response to a failure detection signal enabled while the chip area is in the test mode.

According to an embodiment, there may be provided a repair system. The repair system may include a repair apparatus configured to test whether failure has occurred in a chip area including one or more semiconductor memory chips while the one or more semiconductor memory chips are in a test mode. The repair apparatus may be configured to enable a failure detection signal when the failure has occurred. The repair apparatus may be configured to store a failure address signal. The repair system may include a quality management unit configured to store quality information in response to the failure detection signal. The quality management unit may be configured to output the quality information to an exterior in response to a quality information read command.

According to an embodiment there may be provided a method for managing the quality of an apparatus. The method may include the step of generating test data from a chip area including one or more semiconductor memory chips while the one or more semiconductor memory chips are in a test mode. The method may include the step of checking whether a failure is detected from the chip area based on the test data. The method may include the step of enabling a failure detection signal when the failure is detected. The method may include the step of storing quality information in response to the failure detection signal. The quality information may be stored to allow outputting of the quality information to an exterior.

### BRIEF DESCRIPTION OF THE DRAWINGS

FIG. 1 is a configuration diagram illustrating a representation of an example of a semiconductor memory apparatus according to an embodiment.

FIG. 2 is a configuration diagram illustrating a representation of an example of a quality management unit according to an embodiment.

FIG. 3 is a configuration diagram illustrating a representation of an example of a repair apparatus according to an embodiment.

FIG. 4 is a configuration diagram illustrating a representation of an example of a failed address detection unit according to an embodiment.

FIG. 5 is a configuration diagram illustrating a representation of an example of a failed address storage unit according to an embodiment.

FIG. 6 is a flowchart for explaining a representation of an example of a method for managing an apparatus quality according to an embodiment.

FIG. 7 is a configuration diagram illustrating a representation of an example of an electronic system according to an embodiment.

### DETAILED DESCRIPTION

Hereinafter, a semiconductor memory apparatus, a repair system therefor, and a method for managing an apparatus quality according to various embodiments will be described below with reference to the accompanying drawings through various examples of embodiments.

FIG. 1 is a configuration diagram illustrating a representation of an example of a semiconductor memory apparatus according to an embodiment.

A semiconductor memory apparatus 10 according to an embodiment may include a chip area 110 and a repair system 120.

The chip area 110 may be an area where a semiconductor memory chip with memory cells and peripheral circuits thereof has been formed. The chip area 110 may provide one or more semiconductor memory chips.

The repair system 120 may provide failed address storage and an access routing function to a failed memory cell according to a test result for the chip area 110 in a test mode. The repair system 120 may be configured to manage whether the chip area 110 has been repaired as quality information and output the quality information to an exterior. In an embodiment, the test mode may be, for example but not limited to, a package level test mode or a mounting test mode. For example, the repair system 120 may be configured to perform a test for the chip area 110 while the chip area 110 is in a test mode. The repair system 120 may be configured to determine whether the chip area 110 has been repaired, and to generate the determination of whether the chip area 110 has been repaired as quality information INFO in response to a failure detection signal FAIL_MON enabled while the chip area 110 is in the test mode. The repair system 120 may be configured to output the quality information INFO to an exterior of the repair system 120.

In an embodiment, the repair system 120 may include a repair apparatus 122 and a quality management unit 124.

The repair apparatus 122 may test whether a failure has occurred in each memory cell provided in the chip area 110. The repair apparatus may enable a failure detection signal FAIL_MON when the failure has occurred. The repair apparatus 122 may be configured to store information on a position where the failure has occurred, for example, an address, and to allow a failed cell to be replaced with a redundancy cell when there is a request of access to the failed cell.

The quality management unit 124 may be configured to store quality information INFO indicating the corresponding semiconductor memory apparatus 10 is a chip repaired at a package level or a mounting level when the occurrence of failure is detected in a test for the chip area 110 through the repair apparatus 122, that is for example, when the failure detection signal FAIL_MON is enabled. Such quality information INFO may be configured to be outputted to an exterior of the semiconductor memory apparatus 10. The quality information INFO may be configured to be outputted to an exterior of the semiconductor memory apparatus 10 in response to a quality information read command INFO_RD.

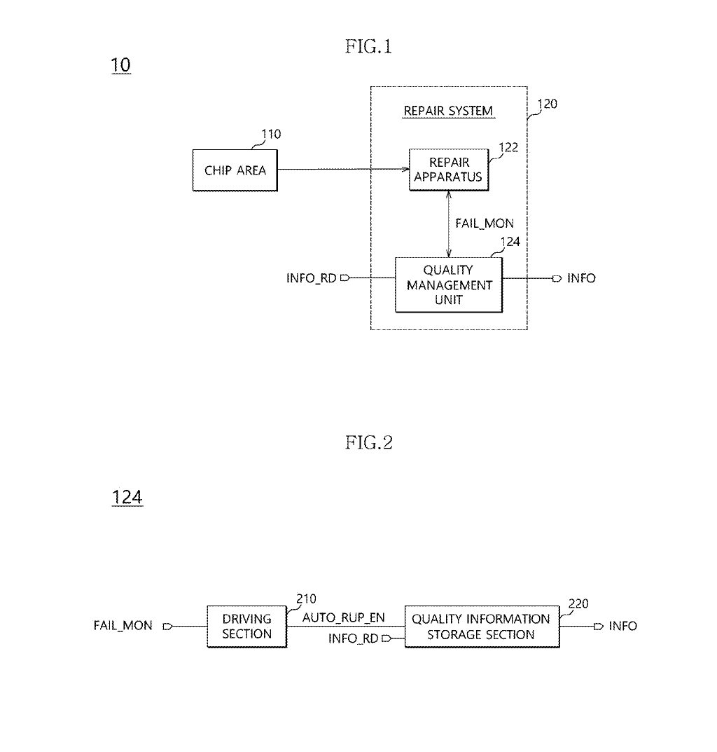

FIG. 2 is a configuration diagram illustrating a representation of an example of the quality management unit according to an embodiment.

The quality management unit 124 according to an embodiment may include a driving section 210 and a quality information storage section 220.

The driving section 210 may generate a quality setting control signal AUTO_RUP_EN. The driving section 210 may generate the quality setting control signal AUTO_RUP_EN in response to the failure detection signal FAIL_MON provided from the repair apparatus 122.

The quality information storage section 220 may be configured to program the quality information INFO, indicating the corresponding semiconductor memory apparatus 10 is a repaired apparatus, in response to the quality setting control signal AUTO_RUP_EN.

In an embodiment, the quality information storage section 220 may be configured using an electrical fuse array (E-fuse array). The electrical fuse array available as the quality information storage section 220, for example, may use an extra fuse of electrical fuse arrays for storing a die identifier ID; however, the embodiments are not limited thereto. For example, the quality information storage section 220 may be configured using a storage apparatus capable of providing information of the semiconductor memory apparatus 10 to an exterior similarly to a fuse array for storing the die identifier. When, for example, the quality information read command INFO_RD is enabled, the quality information storage section 220 may output the quality information INFO, indicating the corresponding semiconductor memory apparatus 10 is an apparatus repaired at the package level or the mounting level, in response to the enable of the quality information read command INFO_RD. The quality information INFO may be easily checked from an exterior.

Even in a chip in which no failure has occurred in a wafer level test, failure may occur in a package test step or a mounting step. The occurrence of the failure in the package test step or the mounting test step may be regarded as failure being progressed. Accordingly, when it is possible to distinguish a semiconductor memory apparatus repaired due to the occurrence of failure in the package test step or the mounting test step from a non-repaired semiconductor memory apparatus, it may be possible to more reliably perform quality management for each product.

In an embodiment, the quality information of the semiconductor memory apparatus, that is, whether the semiconductor memory apparatus has been repaired is automatically stored using the failure detection signal, indicating that failure has occurred in the test mode for a package level test or a mounting test, as a driving signal. The quality information INFO may be outputted to an exterior in response to the quality information read command INFO_RD, so that quality management for each semiconductor memory apparatus becomes possible. That is, it may be possible to automatically store and manage the quality information of the semiconductor memory apparatus simultaneously to a test by using a signal generated in a package level test operation or a mounting test operation without a separate processing process.

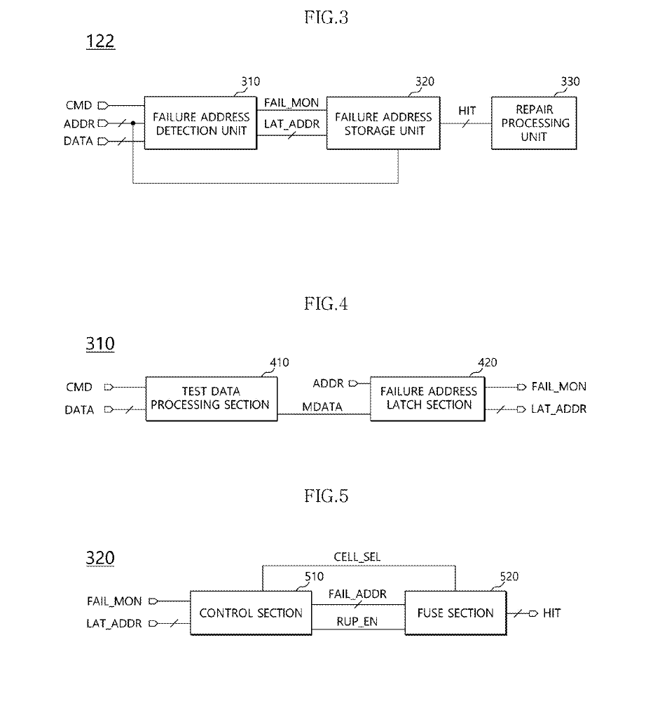

FIG. 3 is a configuration diagram illustrating a representation of an example of the repair apparatus according to the embodiment.

The repair apparatus 122 according to an embodiment may include a failure address detection unit 310, a failure address storage unit 320, and a repair processing unit 330.

The failure address detection unit 310 may be configured to receive an address signal ADDR and test read data DATA. The failure address detection unit 310 may be configured to detect the occurrence of failure in response to a test command CMD. When the failure is detected, the failure address detection unit 310 may be configured to enable the failure detection signal FAIL_MON and output an address latch signal LAT_ADDR indicating a position where the failure has occurred.

The failure address storage unit 320 may receive the address latch signal LAT_ADDR from the failure address detection unit 310. The failure address storage unit 320 may be configured to store the position where the failure has occurred, that is, a failure address in response to the failure detection signal FAIL_MON. The failure address storage unit 320 may be configured to output a hit signal HIT based on the failure address and an external address.

The repair processing unit 330 may enable a redundancy memory cell (block) (not illustrated) based on the hit signal HIT outputted from the failure address storage unit 320. Accordingly, it may be possible to prohibit access to a failed memory cell (block).

FIG. 4 is a configuration diagram illustrating a representation of an example of the failed address detection unit according to an embodiment.

The failure address detection unit 310 according to an embodiment may include a test data processing section 410 and a failure address latch section 420.

The test data processing section 410 may merge the test read data DATA in response to the test command CMD, thereby generating merged test data MDATA. The test read data DATA may be read from a chip area after test write data is written in the chip area.

The failure address latch section 420 may be configured to receive the address signal ADDR and the merged test data MDATA, and to detect whether failure has occurred. When the failure is detected, the failure address latch section 420 may be configured to enable the failure detection signal FAIL_MON. When the failure is detected, the failure address latch section 420 may be configured to output the address latch signal LAT_ADDR indicating the position where the failure has occurred.

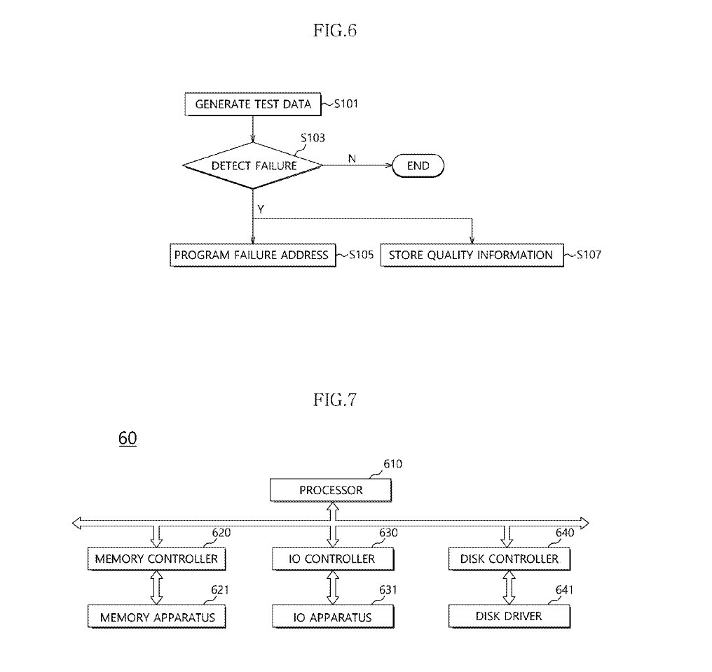

The failure detection signal FAIL_MON and the address latch signal LAT_ADDR generated in the failure address latch section 420 may be provided to a failure address storage unit. FIG. 5 illustrates the failure address storage unit 320 according to an embodiment.

Referring to FIG. 5, the failure address storage unit 320 may include a control section 510 and a fuse section 520.

The control section 510 may output the address latch signal LAT_ADDR as a failure address signal FAIL_ADDR when the failure detection signal FAIL_MON is enabled in the example in which the address latch signal LAT_ADDR is inputted. The control section 510 may be configured to enable a cell selection signal CELL_SEL and a rupture enable signal RUP_EN as the failure detection signal FAIL_MON is enabled.

The fuse section 520 may select an unused fuse cell in response to the cell selection signal CELL_SEL. The fuse section 520 may be configured to program the failure address signal FAIL_ADDR in response to the rupture enable signal RUP_EN as the fuse cell is selected.

The fuse section 520 may include, for example but not limited to, an electrical fuse array. However, the embodiments are not limited thereto. For example, it may be possible to employ all configurations capable of programming the failure address signal FAIL_ADDR.

FIG. 6 is a flowchart for explaining a representation of an example of a method for managing an apparatus quality according to an embodiment.

As the test mode of the package step or the mounting step is enabled, test data may be written in the chip area and be read again, so that test data may be generated (S101). The test data may be merged test data obtained by compressing test read data.

Then, based on the merged test data and an address signal indicating the merged test data, it may be checked whether a failure is detected (S103).

As a result of the check, when the failure is detected (i.e., Y) and the failure detection signal FAIL_MON is enabled, a failure address is programmed (S105). As a result of the check, when the failure is detected (i.e., Y) and the failure detection signal FAIL_MON is enabled, the fact that a corresponding semiconductor memory apparatus has been repaired may be stored as quality information (S107). As a result of the check, when a failure is not detected (i.e., N) the method is ended.

In the present technology, it may be possible to manage whether repair has been performed in a package level test or a mounting level test as quality information. Moreover, since such quality information may be automatically stored in a repair process, an additional operation may not be necessary, and it may be possible to output the quality information to an exterior and to easily and conveniently manage the quality of each semiconductor memory apparatus.

FIG. 7 is a configuration diagram illustrating a representation of an example of an electronic system according to an embodiment.

An electronic system 60 according to various embodiments may include a processor 610, a memory controller 620, and a memory apparatus 621. The electronic system 60 according to the various embodiments may include an IO controller 630, an IO apparatus 631, a disk controller 640, and a disk driver 641.

One or more processors 610 may be provided, and may operate independently or in corporation with another processor. The processor 610 has an environment capable of communicating with other elements, for example, the memory controller 620, the IO controller 630, and the disk controller 640, through buses (a control bus, an address bus, and a data bus).

The memory controller 620 is coupled to one or more memory apparatuses 621. The memory controller 620 receives a request provided from the processor 610, and controls the one or more memory apparatuses 621.

The memory apparatus 621, for example, may be the semiconductor memory apparatuses illustrated in FIG. 1 to FIG. 5. The memory apparatus 621, for example, may implement the method for managing an apparatus quality according to various embodiments associated with FIG. 6. For example, the memory apparatus 621 may store apparatus quality information, indicating whether a repair has been performed, in response to the failure detection signal FAIL_MON generated in the package level test or the mounting level test. The memory apparatus 621 may be configured to output the quality information INFO of the memory apparatus 621 to an exterior in response to the quality information read command INFO_RD.

The IO controller 630 may be coupled between the processor 610 and the IO apparatus 631, and may transfer input from the IO apparatus 631 to the processor 610 or provide a processing result of the processor 610 to the IO apparatus 631. The IO apparatus 631 may include an input apparatus such as a keyboard, a mouse, a touchscreen, and a microphone, and an output apparatus such as a display and a speaker.

The disk controller 640 may control one or more disk drivers 641 under the control of the processor 610.

While certain embodiments have been described above, it will be understood to those skilled in the art that the embodiments described are by way of example only. Accordingly, the semiconductor memory apparatus, the repair system therefor, and the method for managing an apparatus quality described herein should not be limited based on the described embodiments. Rather, the semiconductor memory apparatus, the repair system therefor, and the method for managing an apparatus quality described herein should only be limited in light of the claims that follow when taken in conjunction with the above description and accompanying drawings.

What is claimed is:

1. A semiconductor memory apparatus comprising:
a chip area configured to include one or more semiconductor memory chips; and
a repair system configured to perform a test for the chip area while the chip area is in a test mode, to determine whether the chip area has been repaired, and to generate the determination of whether the chip area has been repaired as quality information in response to a failure detection signal enabled while the chip area is in the test mode.

2. The semiconductor memory apparatus according to claim 1, wherein the repair system comprises:
a repair apparatus configured to test whether failure has occurred in the chip area, to enable the failure detection signal when the failure has occurred, and to store a failure address signal; and
a quality management unit configured to store the quality information in response to the failure detection signal, and to output the quality information to an exterior of the repair system.

3. The semiconductor memory apparatus according to claim 1, wherein the repair system is configured to output the quality information to the exterior of the repair system in response to a quality information read command.

4. The semiconductor memory apparatus according to claim 1, wherein the repair system comprises:
a driving section configured to generate a quality setting control signal in response to the failure detection signal; and
a quality information storage section configured to program the quality information, indicating that the chip area has been repaired, in response to the quality setting control signal.

5. The semiconductor memory apparatus according to claim 4, wherein the quality information storage section is configured to output the quality information in response to a quality information read command received from an exterior of the repair system.

6. The semiconductor memory apparatus according to claim 1, wherein the repair system is configured to include an electrical fuse array for storing the quality information.

7. The semiconductor memory apparatus according to claim 1, wherein the repair system stores the quality information in a part of an electrical fuse array for storing a die identifier ID of the semiconductor memory apparatus.

8. The semiconductor memory apparatus according to claim 1, wherein the test mode includes a package level test mode or a mounting level test mode.

9. A repair system comprising:
a repair apparatus configured to test whether failure has occurred in a chip area including one or more semiconductor memory chips while the one or more semiconductor memory chips are in a test mode, to enable a failure detection signal when the failure has occurred, and to store a failure address signal; and
a quality management unit configured to store quality information in response to the failure detection signal.

10. The repair system according to claim 9, wherein the quality management unit outputs the quality information to an exterior in response to a quality information read command.

11. The repair system according to claim 9, wherein the quality management unit comprises:
a driving section configured to generate a quality setting control signal in response to the failure detection signal; and
a quality information storage section configured to program the quality information, indicating that the chip area has been repaired, in response to the quality setting control signal.

12. The repair system according to claim 9, wherein the repair system is configured to include an electrical fuse array for storing the quality information.

13. The repair system according to claim 9, wherein the repair system stores the quality information in a part of an electrical fuse array for storing a die identifier ID of the semiconductor memory apparatus.

14. The repair system according to claim 9, wherein the test mode includes a package level test mode or a mounting level test mode.

15. A method for managing a quality of a semiconductor memory apparatus, comprising the steps of:
generating test data from a chip area including one or more semiconductor memory chips while the one or more semiconductor memory chips are in a test mode;
checking whether a failure is detected from the chip area based on the test data;
enabling a failure detection signal when the failure is detected; and
storing quality information in response to the failure detection signal,
wherein the quality information is stored to allow outputting of the quality information to an exterior.

16. The method according to claim 15, wherein the quality information is outputted to the exterior in response to a quality information read command.

17. The method according to claim 15, wherein the quality information indicates that the chip area has been repaired.

18. The method according to claim 15, wherein the quality information is stored in an electrical fuse array.

19. The method according to claim 15, wherein the quality information is stored in a part of an electrical fuse array for storing a die identifier ID of the semiconductor memory apparatus.

20. The method according to claim 15, wherein the test mode includes a package level test mode or a mounting level test mode.
